(19) United States
(12) Patent Application Publication
(10) Pub. No.: US 2016/0233055 A1
(43) Pub. Date: Aug. 11, 2016

(54) Apparatus and Method for Metastable Enhanced Plasma Ignition

(71) Applicant: MKS Instruments Inc., Andover, MA (US)

(72) Inventors: Shaun Smith, Malden, MA (US); Steven R. Walther, Andover, MA (US)

(21) Appl. No.: 14/616,431

(22) Filed: Feb. 6, 2015

(51) Int. Cl. H01J 37/32; H05H 1/46

(52) U.S. Cl. CPC H01J 37/3244; H05H 1/46; H01J 37/32458; H01J 37/32009

(57) ABSTRACT

Methods and apparatus for igniting a process plasma within a plasma chamber are provided. A quantity of metastable atoms generated within a metastable generation volume are provided along with an ignition gas to a plasma generation volume defined by a plasma chamber. The quantity of metastable atoms generated is sufficient to allow at least a predetermined quantity of the metastable atoms to flow from a first location within the plasma generation volume to a second location within the plasma generation volume. A process plasma is ignited within the plasma generation volume by applying an electric field to the plasma generation volume that includes the metastable atoms flowed therein.

### FIELD OF THE INVENTION

The invention relates generally to the use of plasmas to generate activated gases containing ions, free radicals, atoms, and molecules. In particular, metastable atoms are flowed into a plasma generation volume to cause a plasma ignition gas to ignite in the presence of an electric field.

### BACKGROUND OF THE INVENTION

Plasma discharges can be used to excite gases to produce activated gases containing ions, free radicals, atoms and molecules. Activated gases are used for numerous industrial and scientific applications including processing solid materials such as semiconductor wafers, powders, and other gases. The parameters of the plasma and the conditions of the exposure of the plasma to the material being processed vary widely depending on the application.

Plasmas can be generated in various ways including DC discharge, radio frequency (RF) discharge, and microwave discharge. DC discharges are achieved by applying a potential between two electrodes in a gas. RF discharges are achieved either by electrostatically or inductively coupling energy from a power supply into a plasma. Parallel plates are typically used for electrostatically coupling energy into a plasma. Induction coils are typically used for inducing current into a plasma. Microwave discharges are achieved by directly coupling microwave energy through a microwave-passing window into a discharge chamber containing a gas. Microwave discharges are advantageous because they can be used to support a wide range of discharge conditions, including highly ionized electron cyclotron resonant (ECR) plasmas.

Capacitively-coupled RF discharges and DC discharges inherently produce high energy ions and, therefore, are often used to generate plasmas for applications where the material being processed is in direct contact with the plasma. Microwave discharges produce dense, low ion energy plasmas. Microwave discharges are also useful for applications where it is desirable to generate ions at low energy and then accelerate the ions to the process surface with an applied potential.

RF inductively coupled plasmas are particularly useful for generating large area plasmas for such applications as semiconductor wafer processing. However, some RF inductively coupled plasmas are not purely inductive because the drive currents are only weakly coupled to the plasma. Consequently, RF inductively coupled plasmas are often inefficient and require the use of high voltages on the drive coils. The high voltages produce high electrostatic fields that cause high energy ion bombardment of reactor surfaces. The ion bombardment deteriorates the reactor and can contaminate the process chamber and the material being processed. The ion bombardment can also cause damage to the material being processed.

Microwave and inductively coupled plasma sources can require expensive and complex power delivery systems. These plasma sources can require precision RF or microwave power generators and complex matching networks to match the impedance of the generator to the plasma source. In addition, precision instrumentation is usually required to ascertain and control the actual power reaching the plasma.

Igniting a plasma can also require power delivery systems that are capable of providing a power large enough to cause ionization of a plasma gas. In current systems, igniting the plasma can require supplying a high electric field (e.g., breakdown field) that is sufficient to cause a gas to excite to a state where a plasma forms, which is guided by, for example, Paschen curves. For microwave plasmas, capacitively coupled plasmas, inductively coupled plasmas, and/or glow discharge plasmas, typically a high electric field (e.g., 0.1 to 10 kV/cm) is applied to a cause an initial breakdown of the gas.

Application of a high voltage to ignite a plasma can cause several difficulties, for example, arcing outside of the ignition window (e.g., the standard operating ranges for pressure, gas flow, and/or gas species for successful ignition) and/or electrical breakdown of dielectrics (e.g., punch through). Additional undesired arcing and electrical breakdown of dielectrics can cause damage to the plasma chamber and/or system parts. Damaged parts can require frequent replacement and can be expensive. Another difficulty of applying a high voltage to ignite is that typically a custom ignition design is needed for different types/shapes of plasma sources.

Current techniques for applying a high voltage to ignite a plasma include use of a high voltage spark plug or high voltage electrodes coupled to the plasma chamber. Another current technique is applying the high voltage directly to a portion of the plasma chamber itself (e.g., block ignition). In addition to the difficulties described above, each of these ignition techniques has difficulties.

Spark plugs typically have a limited lifetime due to for example, relays used in the spark plug, thus requiring frequent replacement. High voltage electrodes typically have to withstand exposure to the plasma during processing. This can cause a limited lifetime for the electrodes and/or limited material options for the electrode. Block ignition creates a potential for plasma arcing and can limit the choices for block materials/coatings.

Therefore, it is desirable to ignite a plasma without arcing, punch through, or exposing parts and/or the plasma chamber itself to high voltages, ion bombardment, radicals, and/or undesirable arcing/heat.

### SUMMARY OF THE INVENTION

Advantages of the invention include minimization of arcing because high voltages are not necessary to cause plasma ignition. Other advantages of the invention include a reduction in the frequency of replacing parts due to the substantial elimination of exposure to high voltages, arcs and/or punch through.

Other advantages include a reduction of cost due to a minimization of the necessity of expensive parts and/or a custom ignition designs. Other advantages include allowing for a wider range of chamber materials/coatings because the material no longer has to withstand high voltages, arcing, and/or punch through.

Other advantages include using the plasma source as a starter plasma for other plasma sources that operate in previously inaccessible pressure and/or flow regimes due to the elimination of the requirement for a high ignition voltage. Other advantages include the ability to perform high rate pulsed plasma processing in processing chambers where impedance conditions for initial breakdown and processing conditions are vastly different due to the ability to ignite with the process gas and avoid switching from an inert gas mixture which is typically currently needed.

Other advantages include a reduction of a tuning range requirement for an inductively coupled plasma due to a reduction in the electric field needed for ignition.

In one aspect, the invention involves a method for igniting a process plasma within a plasma chamber. The method involves providing a plasma chamber defining a plasma generation volume within which the process plasma forms. The method also involves generating a quantity of metastable atoms within a metastable generation volume. The method also involves flowing a gas mixture comprising the generated metastable atoms and an ignition gas into the plasma generation volume, the quantity of metastable atoms generated is sufficient to allow at least a predetermined quantity of the metastable atoms to flow from a first location within the plasma generation volume to a second location within the plasma generation volume. The method also involves igniting the process plasma within the plasma generation volume by applying an electric field to the plasma generation volume that includes the metastable atoms flowed therein.

In some embodiments, the first location is an entry point of the metastable atoms into the plasma generation volume. In some embodiments, the second location is an exit point of excited species generated by the process plasma.

In some embodiments, a location of the metastable generation volume relative to the plasma generation volume is based on a time of life of the metastable atoms, a flow velocity of the ignition gas, or a combination thereof.

In some embodiments, the method involves flowing the gas mixture further comprises distributing the gas mixture substantially evenly throughout the plasma generation volume. In some embodiment, the one or more walls of the plasma chamber comprises a dielectric material.

In some embodiments, the ignition gas comprises Helium, Argon, Krypton, Xenon, Neon or any combination thereof. In some embodiments, the gas mixture further comprises a process gas In some embodiment, the power required to generate the metastable atoms is less than 10% of power required to generate the process plasma. In some embodiments, the plasma chamber is a toroidal shape.

In some embodiments, the plasma chamber is part of an inductively coupled plasma source, a capacitively coupled plasma source, a hollow cathode, a microwave discharge plasma source, or a glow discharge plasma source.

In some embodiments, the metastable atoms are generated with a microplasma generator. In some embodiments, the metastable atoms are generated with an electrical discharge, RF discharge, electron cyclotron resonance discharge, or a dielectric barrier discharge, each discharge generated with an inductively coupled plasma source, a capacitively coupled plasma source, a hollow cathode, a microwave discharge plasma source, or a glow discharge plasma source.

In another aspect, the invention includes a plasma source for generating a process plasma. The plasma source includes a plasma chamber defining a plasma generation volume within which the process plasma forms. The plasma source also includes a metastable atom generator to generate metastable atoms within a metastable generation volume. The plasma source also includes an ignition gas source that flows a gas mixture comprising the generated metastable atoms and an ignition gas into the plasma generation volume, the quantity of metastable atoms generated is sufficient to allow at least a predetermined quantity of the metastable atoms to flow from a first location within the plasma generation volume to a second location within the plasma generation volume. The plasma source also includes a power source for applying an electric field to the plasma generation volume that includes the metastable atoms flowed therein.

In some embodiments, the metastable atom generator is a microplasma generator. In some embodiments, the metastable atom generator is an inductively coupled plasma source, a capacitively coupled plasma source, a hollow cathode, a microwave discharge plasma source, or a glow discharge plasma source

In some embodiments, a location of the metastable generation volume relative to the plasma generation volume is based on a time of life of the metastable atoms, a flow velocity of the ignition gas, or a combination thereof.

In some embodiments, an injector plate positioned between the metastable generation volume and the plasma generation volume. In some embodiments, one or more walls of the plasma chamber comprises a dielectric material. In some embodiments, the ignition gas comprises Helium, Argon, Krypton, Xenon, Neon, or any combination thereof.

In some embodiments, power required to generate the metastable atoms is less than 10% of power required to generate the process plasma. In some embodiments, the plasma chamber is a toroidal shape.

In some embodiments, the plasma chamber is part of an inductively coupled plasma source, a capacitively coupled plasma source, a hollow cathode, a microwave discharge plasma source, or a glow discharge plasma source.

### BRIEF DESCRIPTION OF THE DRAWINGS

The advantages of the invention described above, together with further advantages, may be better understood by referring to the following description taken in conjunction with the accompanying drawings. The drawings are not necessarily to scale, emphasis instead generally being placed upon illustrating the principles of the invention.

FIG. 1 is a schematic representation of a plasma source for producing activated gases, according to an illustrative embodiment of the invention.

FIG. 2 is a schematic representation of a plasma chamber, according to an illustrative embodiment of the invention.

FIG. 3 is a schematic representation of a plasma chamber, according to an illustrative embodiment of the invention.

FIG. 4 is a flow diagram of a method for igniting a plasma, according to an illustrative embodiment of the invention.

FIG. 5A is a graph showing an example of power over time for process plasma ignition according to the prior art.

FIG. 5B is a graph showing an example of power over time for a process plasma ignition in the presence of metastable atoms, according to an illustrative embodiment of the invention.

FIG. 6A is a graph showing an example of peak electric field over time for process plasma ignition according to the prior art.

FIG. 6B is a graph showing an example of peak electric field over time for a process plasma ignition in the presence of metastable atoms, according to an illustrative embodiment of the invention.

### DETAILED DESCRIPTION

In general, in the invention, plasma (e.g., process plasma) ignites within a plasma generation volume when metastable atoms (e.g., atoms or molecules carrying at least ˜2 eV of energy) and a gas (e.g., ignition gas) flow into the plasma generation volume and an electric field is applied to the plasma generation volume. The plasma generation volume is defined by a plasma chamber.

The metastable atoms collisions (surface or with other gas species) create free electrons that allow ignition of a process plasma in the plasma generation volume to occur without requiring high electric field.

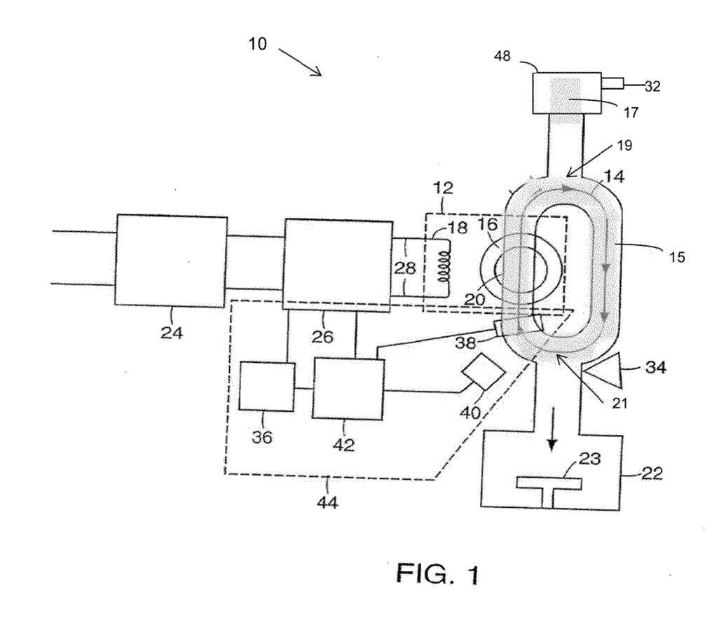

FIG. 1 is a schematic representation of a plasma source 10 for producing activated gases, according to an illustrative embodiment of the invention. The plasma source 10 provides activated gases to a semiconductor process chamber 22. The plasma source 10 includes a power transformer 12, a plasma chamber 20, a gas inlet 32, a metastable generator 48, a switching power supply (voltage supply 24 and switching element 26), and a feedback loop 44.

The power transformer includes a magnetic core 16, a primary coil 18, and a process plasma 14 (once ignited). The power transformer couples power received from the switching power supply into a plasma generation volume 15. The magnetic core 16 wraps around the plasma chamber 20 such that the plasma chamber 20 passes through the magnetic core 16. The primary coil 18 and magnetic core 16 allow the process plasma 14 that is ignited and sustained within the plasma generation volume 15 to form a secondary circuit of the power transformer.

In various embodiments, the power transformer includes two, four or any number of magnetic cores. In various embodiments, the plasma chamber 20 can be made of a dielectric material, such as quartz, alumina or sapphire, or a metal such as aluminum, or a coated metal such as anodized aluminum.

In some embodiments, the switching power supply can be a solid state switching supply, as described in, for example, FIG. 7 and FIG. 8 of U.S. Pat. No. 6,388,226, which is incorporated herein by reference in its entirety.

The metastable atom generator 48 is coupled to the plasma chamber 20. During operation, the metastable atom generator 48 generates metastable atom within a metastable generation volume 17. The metastable atoms along with ignition gas that enters the plasma chamber via gas inlet 32 flow into the plasma generation volume 15 at a first location 19 of the plasma generation volume 15. A percentage of the metastable atoms that flow into the plasma generation volume 15 at a first location 19 flows to a second location 21 within the plasma generation volume 15.

The metastable atoms create free electrons within the plasma generation volume 15. The free electrons accelerate in the presence of an electric field causing ionization of the ignition gas within the plasma volume 15. The free electrons created by the metastable atoms allow for breakdown of the ignition gas with applied electric field intensities for which breakdown of the ignition gas without the metastable atoms is not possible (e.g., intensity that is less than what is expected from Pachen curves). In this manner, the power supplied to the metastable atom generator 48 (e.g., a few Watts up to 10's of Watts) is less than the power supplied to ignition mechanisms in the prior art (e.g., 50 to 300 Watts). In some embodiments, the power required to generate the metastable atoms is less than 10% of power required to generate the process plasma.

With the metastable atoms and ignition gas within the plasma generation volume 15 when the power transformer couples power into the plasma generation volume 15, the process plasma 14 ignites. In this manner, the process plasma ignites without the use of an ignition electrode and/or a high voltage applied to the plasma chamber 20. Once ignition of the process plasma 14 occurs, the metastable atom generator 48 stops generating metastable atoms. In some embodiments, the metastable atom generator 48 continues to generate metastable atoms to flow into the plasma generation volume 15.

In various embodiments, the metastable atom generator 48 generates the metastable atoms with an electrical discharge, RF discharge, electron cyclotron resonance discharge, or a dielectric barrier discharge. In various embodiments, the metastable atom generator 48 is an inductively coupled plasma source, a capacitively coupled plasma source, a hollow cathode, a microwave discharge plasma source, or a glow discharge plasma source. In some embodiments, the metastable atoms generator 48 is a microplasma generator. A microplasma generator can generate a plasma with a self-resonant microwave structure that generates a plasma having a ¼ wavelength of the applied energy. In various embodiments, the microplasma generator generates a plasma within a geometrically small discharge gap or volume. For example, the discharge gap can range from 0.05 mm to 5.0 mm. In some embodiments, the metastable atom generator 48 is a resonant structure.

Gases exit the plasma chamber 20 and enter the process chamber 22 via an outlet of the plasma chamber 20. In some embodiments, the plasma chamber 20 includes multiple gas inlets. In some embodiments, the metastable atom generator 48 has its own inlet and the plasma chamber 20 its own gas inlet. In various embodiments, the plasma chamber 20 has one gas outlet for each magnetic core. In various embodiments, the plasma chamber 20 includes more gas outlets than magnetic cores.

In some embodiments, the ignition gas and a gas used while the plasma 14 is sustained (e.g., process plasma gas) are the same. In some embodiments, the ignition gas and the process plasma gas are different. In various embodiments, the ignition gas is Helium, Argon, Krypton, Xenon, Neon, Radon, Ununoctium, Hydrogen, Nitrogen or any combination thereof. It is apparent to one of ordinary skill, the ignition gas can be any gas capable of igniting into plasma.

A sample holder 23 can be positioned in the process chamber 22 to support the material to be processed. The material to be processed can be biased relative to the potential of the plasma. In some embodiments, a showerhead (not shown) is located between the plasma chamber outlets 50 and the sample holder 23, such that the activated gas is distributed substantially uniformly over the surface of the material to be processed.

The plasma source 10 can also include a measuring circuit 36 for measuring electrical parameters of the primary winding 18. Electrical parameters of the primary winding 18 include the current driving the primary winding 18, the voltage across the primary winding 18, the bus or line voltage that is generated by the voltage supply 24, the average power in the primary winding 18, and the peak power in the primary winding 18. The electric parameters of the primary winding can be continuously monitored.

The power delivered to the plasma can be accurately controlled by monitoring power measurements that are based on a DC bus that feeds an RF section.

The plasma source 10 is useful for processing numerous materials, such as solid surfaces, powders, and gases. The plasma source 10 is particularly useful for providing activated gases in semiconductor processing equipment, such as thin film deposition and etching systems. The plasma source 10 is also particularly useful for photoresist stripping, atomic layer deposition, wafer cleaning, and gate oxide, process chamber cleaning or dielectric modification.

The plasma source can be used to etch numerous materials, such as silicon, silicon dioxide, silicon nitride, aluminum, molybdenum, tungsten and organic materials like photoresists, polyimides and other polymeric materials. The plasma source 10 can be used for plasma enhanced deposition of numerous thin films materials, such as diamond films, silicon dioxide, silicon nitride, and aluminum nitride.

In addition, the plasma source 10 can be used to generate reactive gases, such as atomic fluorine, atomic chlorine, atomic hydrogen, atomic bromine, atomic nitrogen, and atomic oxygen. The plasma source can be used to generate molecular radicals, such as NH, NF, OH and other molecular fragments of stable precursors. Such reactive gases are useful for reducing, converting, stabilizing or passivating various oxides, such as silicon dioxide, tin oxide, zinc oxide and indium-tin oxide. Specific applications include flux-less soldering, removal of silicon dioxide from a silicon surface, passivation of silicon surfaces prior to wafer processing, and surface cleaning of various metal and dielectric materials such as copper, silicon, and silicon oxides.

Other applications of the plasma source 10 include modification of surface properties of polymers, metals, ceramics and papers. In addition, the plasma source 10 may be used to generate high fluxes of atomic oxygen, atomic chlorine, or atomic fluorine for sterilization.

In various embodiments, the surface material of the plasma chamber is selected based on applications and/or gas chemistries to be used during a particular process. For example, quartz is relatively stable to oxygen and chlorine plasmas, but it can be etched in fluorine and hydrogen plasmas. For generating plasmas containing fluorine, the surface of the plasma chamber can be made of aluminum, magnesium, yttrium, or their compounds because these elements can have stable fluorides.

In various embodiments, the composition of the process gases can be tailored to minimize erosion of the plasma chamber surface. For example, surfaces containing aluminum oxide, such as sapphire, alumina, or anodized aluminum, can be eroded by a hydrogen plasma. Hydrogen ions first reduce aluminum oxide and subsequently convert it to volatile aluminum hydride. Addition of a small amount of oxygen in hydrogen, in the form of O₂ or H₂O and in the range of 1-1000 ppm, can stabilize the aluminum oxide surface and substantially reduce its erosion

The plasma current and plasma current density of the plasma 14 generated by the plasma source 10 can be selected to optimize dissociation of particular gases for particular applications. For example, the plasma current and plasma current density can be selected to optimize NF3 dissociation. NF3 is widely used as a source of fluorine for chamber cleaning and numerous other applications. NF3 is relatively expensive. Optimizing the plasma source 10 for high NF3 dissociation rates improves the gas utilization rate and reduces the overall cost of operating the system. In addition, increasing the dissociation rate of NF3 is desirable because it reduces the release of environmentally hazardous gases into the atmosphere.

The dissociation of NF3 is caused by collisions between the NF3 molecules and the electrons and hot gases in the plasma. The density of electrons in the plasma source is approximately proportional to the plasma current density. There exists an optimal range of plasma current densities that maximize the dissociating of NF3 molecules. In one embodiment, a toroidal plasma 14 having a length of approximately 40-60 cm, the optimal plasma current density for efficiently dissociating NF3 gas is between 5-20 A/cm². In one embodiment, a toroidal plasma 14 having a cross sectional area of 3-10 cm², this current density range corresponds to a total toroidal plasma current in the range of approximately 20-200 A.

The materials used in the internal surface of the plasma chamber 20 and the elements that connect the output of the plasma chamber 20 to the process chamber 22 can be carefully chosen, especially if the plasma source will be used to generate chemically reactive species. Materials can be selected to meet several requirements. One requirement of the materials is that the creation of contamination that results from corrosion or deterioration of the material caused by interaction of the materials with the process gases should be minimized. Another requirement of the materials is that they have minimal erosion when exposed to process gases. Another requirement of the materials is that they should minimize recombination and deactivation of the reactive gas, thus maximizing reactant delivery to the process chamber.

Anodized aluminum has some advantages for semiconductor processing applications. One advantage is that anodized aluminum can be grown directly on an underlying aluminum base through an electrolytic process. The resulting film has excellent adherence properties. Another advantage is that anodized aluminum has a thermal conductivity that is approximately 15 times greater than the thermal conductivity of quartz. Therefore, the inside surface of plasma chambers that are formed with anodized aluminum will remain relatively cool, even with significant incident power density.

Another advantage is that anodized aluminum is chemically inert to many atomic species (F, O, Cl, etc.) as long as there is no or only low-energy ion bombardment present. Anodized aluminum is particularly advantageous for fluorine chemistries because it has a low recombination coefficient for atomic fluorine. Also, anodized aluminum is a material that is commonly used and accepted for semiconductor materials processing applications.

Quartz also has some advantages for semiconductor processing applications. Quartz is available in extremely high purity and is commonly used and accepted in the semiconductor industry. Also, quartz is stable with numerous reactive species including O, H, N, Cl, and Br. In particular, quartz has a low surface recombination coefficient for atomic oxygen and hydrogen. Also, quartz has a low thermal coefficient of expansion and has relatively high resistance to thermal shock. In addition, quartz has a high softening and melting point and, therefore, it is relatively easy to form a process chamber from quartz.

Fluoropolymers also have some advantages for semiconductor processing applications. Examples of some fluoropolymers are PTFE, PFE, PFA, FEP, and Teflon™. The recombination rate for many fluoropolymers is relatively low. Fluoropolymers also are relatively inert to most atomic species including atomic fluorine and atomic oxygen. In addition, the purity of fluoropolymers is relatively high and fluoropolymers are available in both bulk form (tube, sheet, etc.) and in thin film form.

In some embodiments, fluoropolymers, however, can be eroded by ions in the plasma. Also, the maximum operating temperature that fluoropolymers can tolerate is significantly less than the maximum temperature that quartz can tolerate. In addition, the thermal conductivity of fluoropolymers is relatively low. Therefore, in some embodiments, fluoropolymers are most useful for constructing the transport sections outside of the plasma chamber.

It is apparent to one of ordinary skill that the plasma source shown above in FIG. 1 is one exemplary configuration for a plasma source for which a process plasma can be ignited and sustained inside of a plasma generation volume and that many possible configurations for a plasma source are possible and applicable to the invention. In various embodiments, other plasma source configurations known in the art are modified to allow for metastable atoms to excite the ignition gas to allow for ignition of the process plasma with field intensities that are lower than field intensities required for a neutral ignition gas.

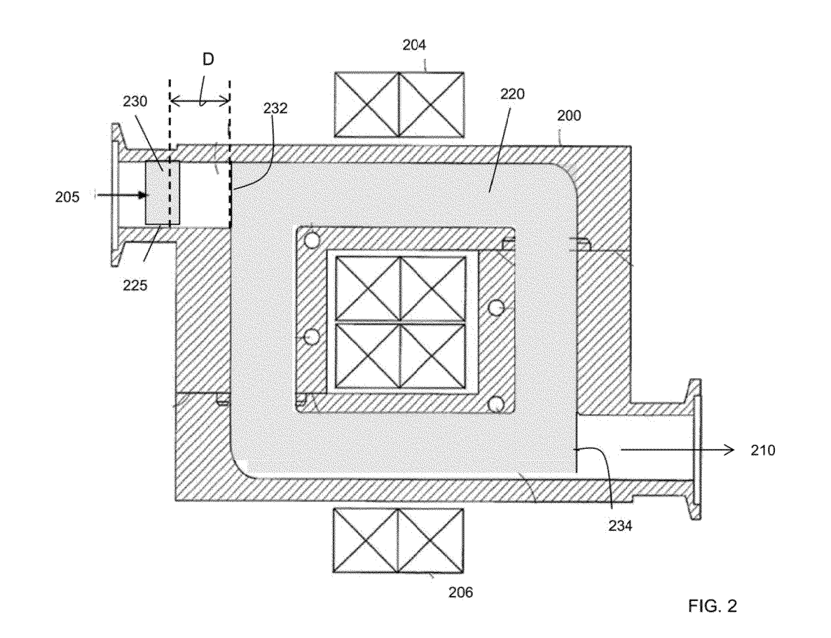

FIG. 2 is a schematic representation of a plasma chamber 200, according to an illustrative embodiment of the invention. The plasma chamber 200 is a toroidal shape and includes a plasma generation volume 220, a metastable generator 225, an inlet 205 and an outlet 210. The plasma chamber 200 is surrounded by magnetic cores 204 and 206.

In this embodiment, the metastable generator 225 resides within the plasma chamber 200. The metastable generator 225 can generate metastable atoms by igniting and sustaining a plasma within a metastable generation volume 230. The plasma used to generate the metastable atoms can have a smaller density then the density of the process plasma and/or exist in a smaller volume that the volume of that the process plasma exists within. Thus, the power required to generate the metastable atoms can be less than the power required to sustain the process plasma. For example, to generate the metastable atoms the power required can be a few Watts to 10's of Watts, while the power to sustain the plasma can be greater than 1 kilowatt.

During operation, an ignition gas is flowed through the inlet 205 of the plasma chamber 200. The ignition gas is used by the metastable generator 225 to generate a plasma. The plasma causes generation of metastable atoms within the metastable generation volume 230. The ignition gas and the metastable atoms flow into the plasma generation volume 220 at a first location 232. At least a portion of the metastable atoms that flow into the plasma generation volume flows to a second location 234 of the plasma generation volume 220. An electric field is applied to the plasma generation volume 220 via the magnetic cores 204 and 206 and the process plasma ignites within the plasma generation volume 220.

In some embodiments, the metastable generation volume 230 is located at a distance D from the plasma generation volume 220. In some embodiments, the distance D is based on the lifetime of the metastable atoms, such that there is sufficient life time for the metastable atoms to flow into and create free electrons within the plasma generation volume 220.

The distance D can be less than or equal to the mean free path (L) for loss of the metastable atoms. The mean free path (L) can be defined as the distance covered by the metastable atoms before de-excitation due to collisions. The mean free path can be defined as follows:

L=V (gas velocity)*Tms (metastable species lifetime) EQN. 1

where V is metastable atom velocity and Tms is metastable atom lifetime. Tms can be a function of collision frequency, that is, the frequency of collisions of the metastable atoms with the ignition gas and the plasma chamber walls collisions.

In some embodiments, Tms is on the order of milliseconds. In some embodiments, Tms is shorter than milliseconds, for example, in embodiments having high gas densities and/or small gas channels. The metastable atom survival quantity can decrease with distance as follows:

N(z)/N(0)=ê(−z/L); EQN. 2

where N(z) is the metastable atom flux at position ‘z’ within the plasma chamber, and N(0) is the metastable atom flux at the start (position 0) within the plasma chamber.

In some embodiments, the gas velocity V is large enough to allow at least 0.1% of the initial metastable atom flux (e.g., N(0)) to reach an exit of the plasma chamber.

In some embodiments, the distance D is based on ensuring that substantially all of the free electrons generated in the metastable generation volume 230 do not transport into the plasma generation volume 220. In some embodiments, the distance D is based on a flow velocity of the ignition gas, pressure inside of the plasma chamber, geometry of the plasma chamber.

In some embodiments, an injector plate is positioned between the metastable generation volume 230 and the plasma generation volume 220. In some embodiments, the metastable generation volume 230 is outside of the plasma chamber 200. In various embodiments, the plasma chamber 200 is part of an inductively coupled plasma source, a capacitively coupled plasma source, a hollow cathode, a microwave discharge plasma source, or a glow discharge plasma source.

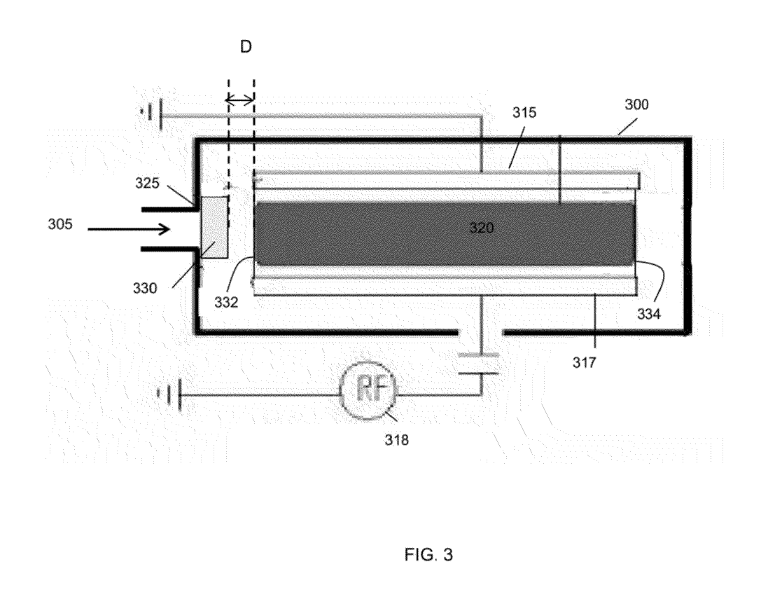

For example, FIG. 3 is a schematic representation of a plasma chamber 300 of a capacitvely coupled plasma source, according to an illustrative embodiment of the invention. The plasma chamber 300 is a cylindrical and includes a plasma generation volume 320, a metastable generator 325, an inlet 305 and two electrodes, 315 and 317, coupled to an RF power supply 318.

In this embodiment, the metastable generator 325 resides within the plasma chamber 300. The metastable generator 325 can generate metastable atoms by igniting and sustaining a plasma within a metastable generation volume 330. The plasma used to generate the metastable atoms can have a smaller density then the density of the process plasma. Thus, the power required to generate the metastable atoms can be much less than the power required to sustain the process plasma. For example, to generate the metastable atoms the power required can be a few Watts to tens of Watts, while the power to sustain the plasma can be greater than 1 kilowatt.

During operation, an ignition gas is flowed through the inlet 305 of the plasma chamber 300. The ignition gas is used by the metastable generator 325 to generate a plasma. The plasma causes generation of metastable atoms within the metastable generation volume 330. The ignition gas and the metastable atoms flow into a first location 332 of the plasma generation volume 320. At least a portion of the metastable atoms flow into a second location 334 of the plasma generation volume 320. An electric field is applied to the plasma generation volume 320 via the RF power supply 318 and the process plasma ignites within the plasma generation volume 320.

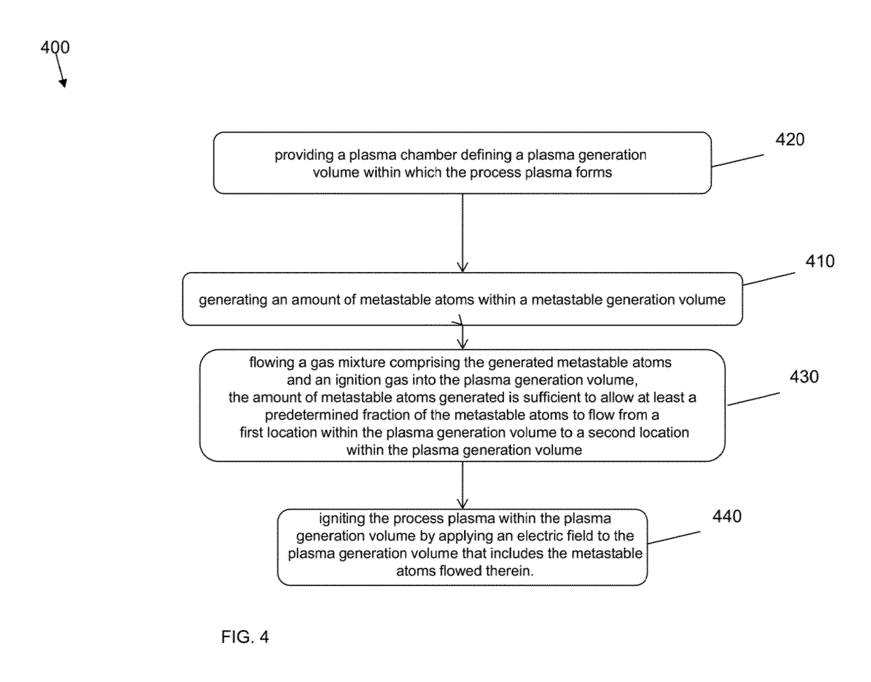

FIG. 4 is a flow diagram 200 of a method for igniting a process plasma within a plasma chamber (e.g., plasma chamber 200 as shown above in FIG. 2).

The method involves providing a plasma chamber defining a plasma generation volume (e.g., plasma generation volume 220 as shown above in FIG. 2) within which the process plasma forms (Step 210).

The method also involves generating a quantity of metastable atoms within a metastable generation volume (e.g., metastable generation volume 220 as shown above in FIG. 2) (Step 220). The method also involves flowing a gas mixture including the generated metastable atoms and an ignition gas into the plasma generation volume (Step 230). In some embodiments, the gas mixture includes a process gas (e.g., a gas used keep an ignited plasma on). The quantity of metastable atoms generated is sufficient to allow at least a predetermined quantity of the metastable atoms to flow from a first location within the plasma generation volume to a second location within the plasma generation volume.

In some embodiments, the predetermined quantity depends on desired power level for ignition. In various embodiments, between 1% and 0.1% of the metastables atoms generated flow from the first location within the plasma generation volume to the second location within the plasma generation volume. The metastable survival quantity can decrease as shown above in EQN. 2

In some embodiments, the quantity of metastable atoms generated is sufficient to allow metastable atoms to be substantially uniform throughout the plasma generation volume. In these embodiments, the predetermined quantity is very close to 1.

In some embodiments, the quantity of metastable atoms generated is based on a predetermined ignition voltage. For example, assuming the same plasma source, for a low ignition voltage a higher number of metastable atoms can be generated, for a higher ignition voltage a lower number of metastable atoms can be generated. In various embodiments, the desired electric field (loop RF field) is in the range of 5 to 50 V/cm. In some embodiments, the desired electric field is a function of pressure and species.

In some embodiments, the quantity of metastable atoms generated is based on a peak electric field desired within the plasma generation volume before, during and after process plasma ignition.

For example, for a toroidal plasma chamber having a loop length of 20 cm, the peak electric field is 5 V/cm giving a total voltage of 1000 volts.

The method also involves igniting the process plasma within the plasma generation volume by applying an electric field to the plasma generation volume that includes the metastable atoms flowed therein (Step 240).

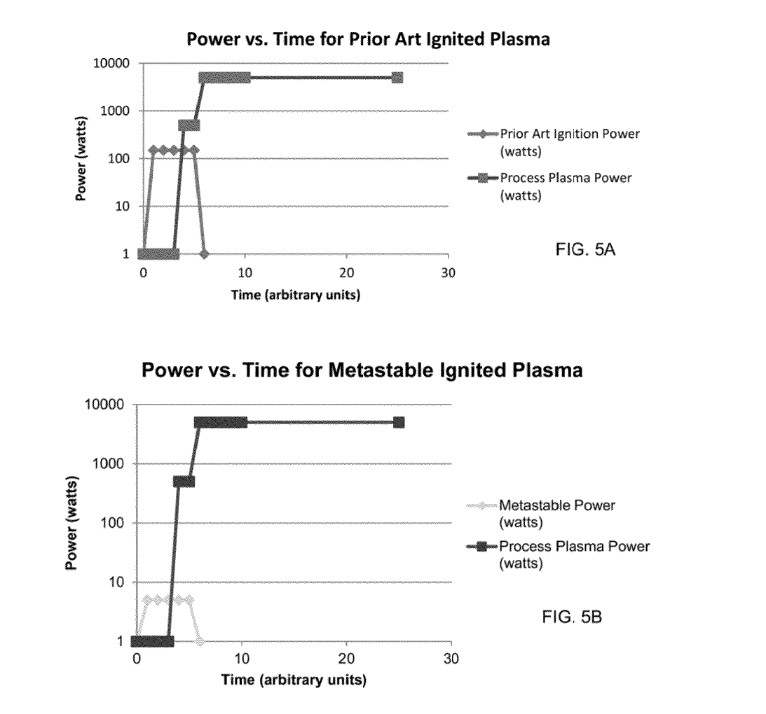

FIG. 5A is a graph showing an example of power over time for process plasma ignition according to the prior art. FIG. 5B is a graph showing an example of power over time for a process plasma ignition in the presence of metastable atoms, according to an illustrative embodiment of the invention. As can be seen in the figures, for ignition in the presence of metastable atoms, the power required is approximately ten times less than the power required for ignition according to the prior art.

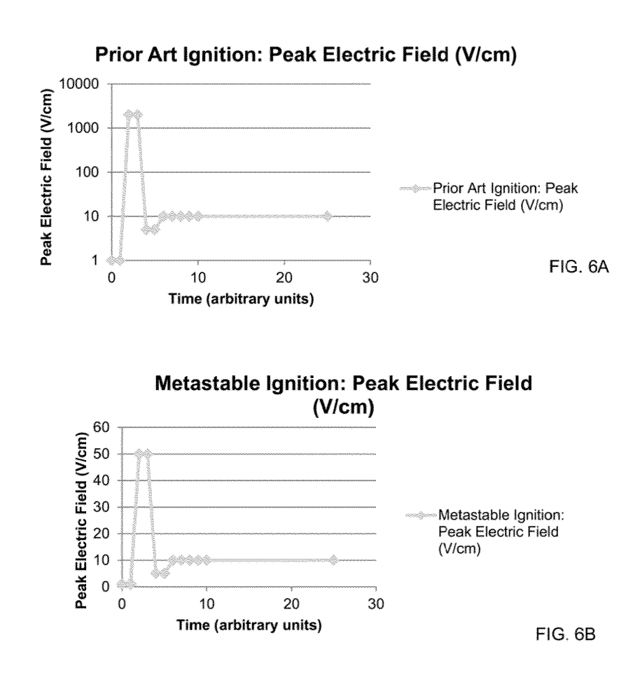

FIG. 6A is a graph showing an example of peak electric field over time for process plasma ignition according to the prior art. FIG. 6B is a graph showing an example of peak electric field over time for a process plasma ignition in the presence of metastable atoms, according to an illustrative embodiment of the invention. As can be seen in the figures, for ignition in the presence of metastable atoms, the peak electric field required is approximately forty times less than the peak electric field required for ignition according to the prior art.

While the invention has been particularly shown and described with reference to specific embodiments, it should be understood by those skilled in the art that various changes in form and detail may be made therein without departing from the spirit and scope of the invention as defined by the appended claims.

What is claimed is:

1. A method for igniting a process plasma within a plasma chamber, the method comprising:
providing a plasma chamber defining a plasma generation volume within which the process plasma forms;
generating a quantity of metastable atoms within a metastable generation volume;
flowing a gas mixture comprising the generated metastable atoms and an ignition gas into the plasma generation volume, the quantity of metastable atoms generated is sufficient to allow at least a predetermined quantity of the metastable atoms to flow from a first location within the plasma generation volume to a second location within the plasma generation volume; and
igniting the process plasma within the plasma generation volume by applying an electric field to the plasma generation volume that includes the metastable atoms flowed therein.

2. The method of claim 1 wherein the first location is an entry point of the metastable atoms into the plasma generation volume.

3. The method of claim 1 wherein the second location is an exit point of excited species generated by the process plasma.

4. The method of claim 1 wherein a location of the metastable generation volume relative to the plasma generation volume is based on a time of life of the metastable atoms, a flow velocity of the ignition gas, or a combination thereof.

5. The method of claim 1 wherein flowing the gas mixture further comprises distributing the gas mixture substantially evenly throughout the plasma generation volume.

6. The method of claim 1 further wherein one or more walls of the plasma chamber comprises a dielectric material.

7. The method of claim 1 wherein the ignition gas comprises Helium, Argon, Krypton, Xenon, Neon or any combination thereof.

8. The method of claim 1 wherein the gas mixture further comprises a process gas.

9. The method of claim 1 wherein power required to generate the metastable atoms is less than 10% of power required to generate the process plasma.

10. The method of claim 1 wherein the plasma chamber is a toroidal shape.

11. The method of claim 1 wherein the plasma chamber is part of an inductively coupled plasma source, a capacitively coupled plasma source, a hollow cathode, a microwave discharge plasma source, or a glow discharge plasma source.

12. The method of claim 1 wherein the metastable atoms are generated with a microplasma generator.

13. The method of claim 1 wherein the metastable atoms are generated with an electrical discharge, RF discharge, electron cyclotron resonance discharge, or a dielectric barrier discharge, each discharge generated with an inductively coupled plasma source, a capacitively coupled plasma source, a hollow cathode, a microwave discharge plasma source, or a glow discharge plasma source.

14. A plasma source for generating a process plasma, the plasma source comprising:
a plasma chamber defining a plasma generation volume within which the process plasma forms;
a metastable atom generator to generate metastable atoms within a metastable generation volume;
an ignition gas source that flows a gas mixture comprising the generated metastable atoms and an ignition gas into the plasma generation volume, the quantity of metastable atoms generated is sufficient to allow at least a predetermined quantity of the metastable atoms to flow from a first location within the plasma generation volume to a second location within the plasma generation volume; and
a power source for applying an electric field to the plasma generation volume that includes the metastable atoms flowed therein.

15. The plasma source of claim 14 wherein the metastable atom generator is a microplasma generator.

16. The plasma source of claim 14 wherein metastable atom generator is an inductively coupled plasma source, a capacitively coupled plasma source, a hollow cathode, a microwave discharge plasma source, or a glow discharge plasma source

17. The plasma source of claim 14 wherein a location of the metastable generation volume relative to the plasma generation volume is based on a time of life of the metastable atoms, a flow velocity of the ignition gas, or a combination thereof.

18. The plasma source of claim 14 further comprising an injector plate positioned between the metastable generation volume and the plasma generation volume.

19. The plasma source of claim 14 wherein one or more walls of the plasma chamber comprises a dielectric material.

20. The plasma source of claim 14 wherein the ignition gas comprises Helium, Argon, Krypton, Xenon, Neon, or any combination thereof.

21. The plasma source of claim 14 wherein the gas mixture further comprises a process gas.

22. The plasma source of claim 14 wherein power required to generate the metastable atoms is less than 10% of power required to generate the process plasma.

23. The plasma source of claim 14 wherein the plasma chamber is a toroidal shape.

24. The plasma source of claim 14 wherein the plasma chamber is part of an inductively coupled plasma source, a capacitively coupled plasma source, a hollow cathode, a microwave discharge plasma source, or a glow discharge plasma source.
